(19) United States
(12) Patent Application Publication
(10) Pub. No.: US 2008/0124964 A1
(43) Pub. Date: May 29, 2008

(54) Card connection apparatus and its applications

(75) Inventor: Tsung-Pi Chen, Chang Hwa (TW)

Correspondence Address: REED SMITH LLP, Suite 1400, 3110 Fairview Park Drive, Falls Church, VA, 22042, US

(73) Assignee: K.S. Terminals, Inc.

(21) Appl. No.: 11/703,160

(22) Filed: Feb. 7, 2007

(30) Foreign Application Priority Data
Nov. 27, 2006 (TW) 95220891

(51) Int. Cl. H05K 7/16

(52) U.S. Cl. 439/326

(57) ABSTRACT

The invention provides a card connection apparatus and its applications, wherein the card connection apparatus includes a shell, an insulator housing and a plurality of metal terminal positioned inside the insulator housing. Paired pivot bearings are set up on the nook of the lateral wall of the insulator housing, and the end of the pivot bearing joints a resistive cylinder having a bigger internal diameter than that of one of the pivot bearings. The shell is used to seal the insulator housing, wherein at least one holding portion is provided on the edge of the shell for holding the shell, and a plurality of long pivot slits are opened on the lateral wall of the shell at the same side of the holding portion in order to provide a passage for the resistive cylinder. Moreover, an L-shaped bending portion is further established at the end of the long pivot slit for hooking the resistive cylinder. Furthermore, a plurality of metal terminals, including a metal body and two holding pieces being joined both sides of metal body, are used for providing electronic connection with the chip. When the chip, e.g. a SIM card, is inserted into the shell, the holding pieces would interfere with the chip against the direction of the movement of metal terminals.

### FIELD OF THE INVENTION

The present invention relates to a connection apparatus, and more particularly to a card connection apparatus used for placing therein a Subscriber Identity Module (SIM) card in a portable communication device.

### BACKGROUND OF THE INVENTION

As shown in FIG. 1A, the conventional card connection apparatus 100, which is applied within a portable communication device for placing therein the Subscriber Identity Module (SIM) card or other digital signal processing chips, usually includes an iron shell 102 and a plastic body 104. Wherein, pivot holes 106 are respectively formed on the end portions of both sides of the iron shell 102 to be respectively assembled with the pivot axels 108 disposed on the end portions of the two lateral sides of the plastic body 104. Accordingly, the iron shell 102 is pivotally connected to the plastic body 104 so as to rotate freely on the pivot axels 108. Therefore, the iron shell 102 can be opened and closed on the plastic body 104. The pivot axels 108 of the conventional card connection apparatus 100 is a cylinder which may fall off due to insufficient retaining force. Furthermore, the iron shell 102 is not easy to be manufactured.

FIG. 1B schematically illustrates a plastic body of a conventional card connection apparatus. As shown in the figure, a plurality of metal terminals 110 are mounted within the plastic body 104 for being electrically connected with cards such as the SIM card. Wherein, the metal terminals 110 mounted within the plastic body 104 may deform the plastic body 104 due to an inadequate design, and sometimes it may even cause the metal terminals 110 to fall off. Therefore, there are many defects in the currently sold card connection apparatuses on the market, and the designs of them are inadequate and needed to be improved.

### SUMMARY OF THE INVENTION

For solving the above-mentioned problems in prior arts, the invention provides a card connection apparatus and its applications, wherein the card connection apparatus includes a shell, an insulator housing and a plurality of metal terminal positioned inside the insulator housing. Paired pivot bearings are set up on the nook of the lateral wall of the insulator housing, and the end of the pivot bearing joints a resistive cylinder having a bigger internal diameter than that of one of the pivot bearings. The shell is used to seal the insulator housing, wherein at least one holding portion is provided on the edge of the shell for holding the shell, and a plurality of long pivot slits are opened on the lateral wall of the shell at the same side of the holding portion in order to provide a passage for the resistive cylinder. Moreover, an L-shaped bending portion is further established at the end of the long pivot slit for hooking the resistive cylinder. Furthermore, a plurality of metal terminals, including a metal body and two holding pieces being joined both sides of metal body, are used for providing electronically connection with the chip. When a chip, e.g. a SIM card, is inserted into the shell, the holding pieces would interfere with the chip, and impede the movement of the card along the direction of metal terminals.

Therefore, the major objective of the invention is to provide a card connection apparatus with reduced cost and a more adequate design.

The other objective of the invention is to provide a card connection apparatus which is convenient for the user to replace the card such as a SIM card disposed within the card connection apparatus.

A further objective of the invention is to provide a heavy-duty card connection apparatus which can provide a stable surrounding for accessing card data.

A still further objective of the invention is to provide a wireless communication device having a card connection apparatus which can reduce the cost and conform to the requirements of a more adequate design.

A yet further objective of the invention is to provide a wireless communication device having a card connection apparatus which can facilitate the user to replace the card received within the wireless communication device.

Another objective of the invention is to provide a wireless communication device having a heavy-duty card connection apparatus which can provide a stable surrounding for accessing card data.

A still further objective of the invention is to provide a digital electric device having a card connection apparatus which can reduce the cost and conform to the requirements of a more adequate design.

A yet further objective of the invention is to provide a digital electric device having a card connection apparatus which can facilitate the user to replace the card received within the digital electric device.

Another objective of the invention is to provide a digital electric device having a heavy-duty card connection apparatus which can provide a stable surrounding for accessing card data.

### BRIEF DESCRIPTION OF THE DRAWINGS

The above objectives and advantages of the present invention will become more readily apparent to those ordinarily skilled in the art after reviewing the following detailed description and accompanying drawings, in which:

FIG. 1A is a perspective view schematically illustrating a conventional card connection apparatus;

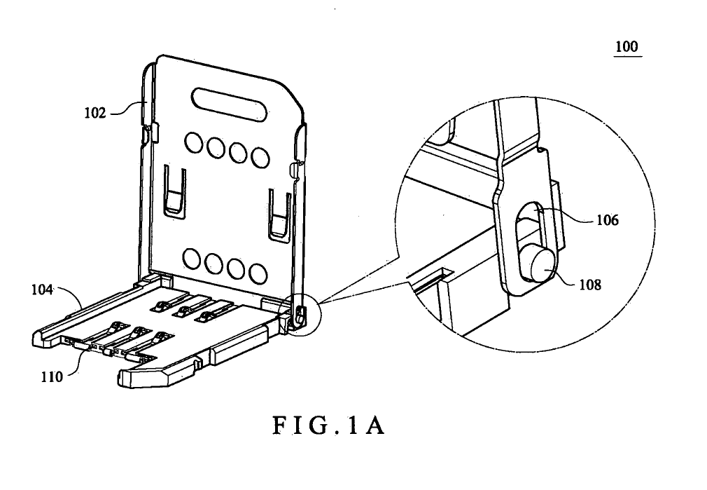

FIG. 1B is a three-dimensional perspective view schematically illustrating a conventional card connection apparatus;

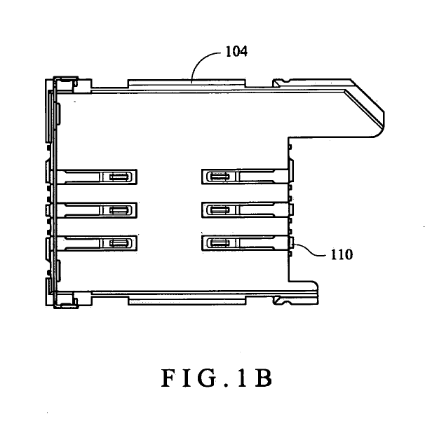

FIG. 2 is a perspective view schematically illustrating a plastic body of a card connection apparatus according to the invention;

FIG. 3 is a partially enlarged diagram schematically illustrating a card connection apparatus according to the invention;

FIG. 4 is a partially enlarged diagram schematically illustrating the shell according to the invention;

FIG. 5 is a perspective view schematically illustrating an operation of a card connection apparatus according to the invention;

FIG. 6 is a perspective view schematically illustrating an operation of a card connection apparatus according to the invention;

FIG. 7 is a perspective view schematically illustrating a card connection apparatus according to the invention;

FIG. 8 is a perspective view schematically illustrating the metal terminals according to the invention;

FIG. 9 is a partially enlarged diagram schematically illustrating the metal terminals according to the invention;

FIG. 10 is a perspective view schematically illustrating a card connection apparatus according to the invention installed on a wireless communication device; and

FIG. 11 is a perspective view schematically illustrating a card connection apparatus according to the invention installed on a PDA.

### DETAILED DESCRIPTION OF PREFERRED EMBODIMENTS

The invention discloses a card connection apparatus and its applications, which include a digital electric device having a card connection apparatus. The digital electric device is selected from a photocopy machine, a portable computer, a desktop computer, a Digital Multimedia Broadcasting (DMB) device, a game console, an electric storage displaying media (such as the electric paper), a mobile communication device such as a cell phone, a Personal Digital Assistant (PDA), a Global Positioning System (GPS), a POS, a POI, a karaoke machine, a video phone, a hand-held data processor, a digital billboard, a television wall, an Automated Teller Machine (ATM), a stock trade system, and a tour guide system, etc . . . The basic theory of the card connection apparatus of any one of the above-mentioned devices and the frameworks of these digital devices are well-known by those skilled in the art and will not be described in details here. Meanwhile, it is to state in advance that the referenced drawings described below are graphical illustrations of the related structures of the invention and are not necessarily drawn in practical scales.

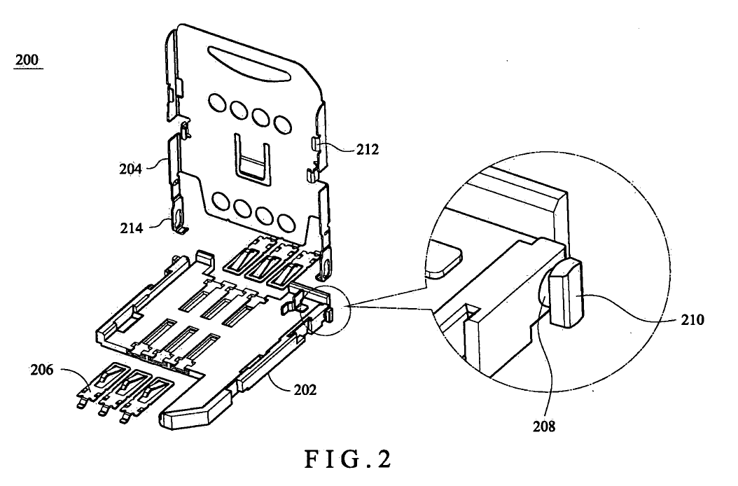

FIG. 2 schematically illustrates a card connection apparatus provided by the invention. As shown in FIG. 2, the card connection apparatus 200 of the invention is a Subscriber Identity Module (SIM) card connection device, which includes an insulator housing 202, a shell 204, and a plurality of metal terminals 206 installed within the insulator housing 202. Wherein, the insulator housing 202 can be made of plastic. Paired pivot bearings 208 are set up on the nook of the lateral wall of the insulator housing 202, and the end of the pivot bearing 208 joints a resistive cylinder 210 having an internal diameter bigger than that of the pivot bearing 208. The shell 204 can be made of metal for sealing the insulator housing 202. At least one holding portion 212 is located on the edge of the shell 204 for holding the shell 204, and, at the same side of the holding portion 212, a plurality of long pivot slits 214 are opened at the lateral wall of the shell 204 in order to provide a passage for the resistive cylinder 210.

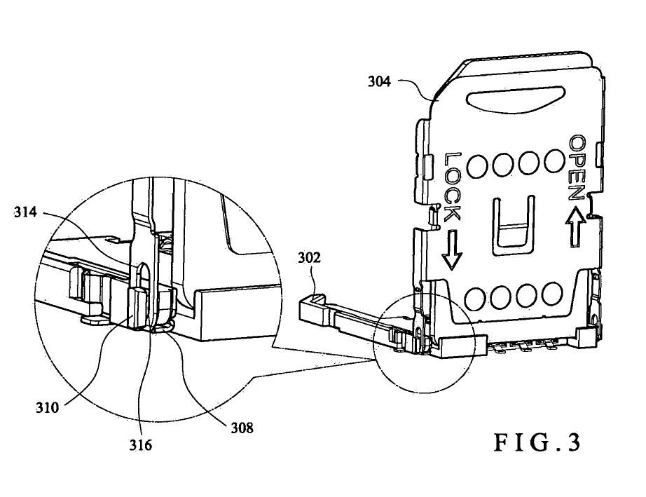

FIG. 3 is a partially enlarged diagram illustrating the card connection apparatus of the invention. As shown in the figure, the shell 304 is pivotally connected to the insulator housing 302 so as to rotate freely on the axle formed by pivot bearings 308. The end of the long pivot slit 314 of the shell 304 is further established an L-shaped bending portion 316. The L-shaped bending portion 316 is made of metal. It hooks the resistive cylinder 310 while the shell 304 is closed to provide firm retaining force for the shell 304 and the insulator housing 302 in the vertical direction. Accordingly, the shell 304 is firmly fixed to the insulator housing 302 by the L-shaped bending portion 316 and thus facilitates the operation of the user.

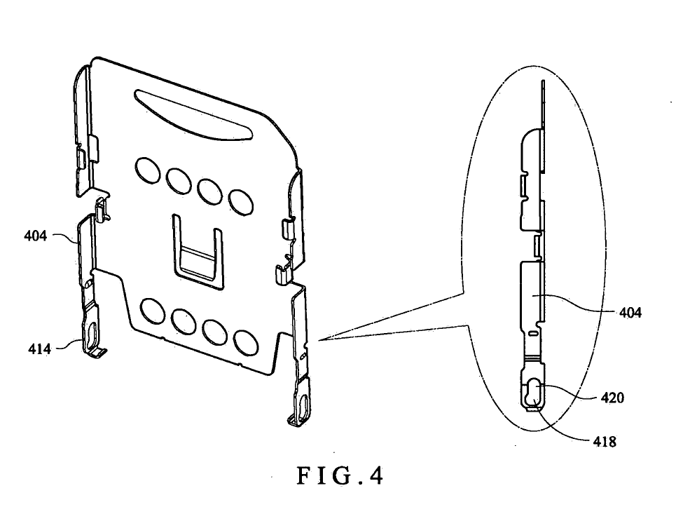

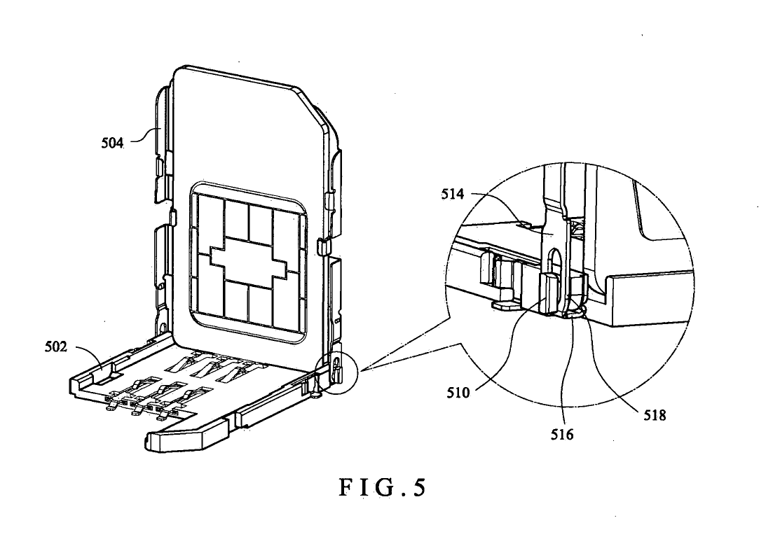

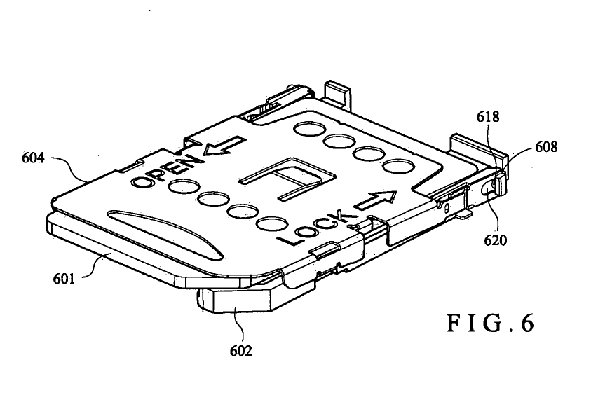

FIG. 4 is a partially enlarged diagram illustrating the shell provided by the invention. As shown in the figure, the long pivot slit 414 of the shell 404 has two circle centers located in the first receiving hole 418 and the second receiving hole 420 respectively. As shown in FIG. 5, when the shell 504 is closed, the L-shaped bending portion 516 hooks the resistive cylinder 510 of the insulator housing 502 to provide retaining force for the shell 504 and the insulator housing 502 in the vertical direction. The L-shaped bending portion 516 firmly fixes the shell 504 on the insulator housing 502 along the vertical direction so that the user can easily insert the SIM card 601. At this moment, the pivot bearing 508 of the insulator housing 502 is fixed within the first receiving hole 518 of the long pivot slit 514. In another example, as shown in FIG. 6, when the pivot bearing 608 of the insulator housing 602 is moved from the first receiving hole 618 to the second receiving hole 620, the end portion of the shell 604 near the pivot bearing 608 will be raised to provide a space for the SIM card 601 to slip into the insulator housing 602 and eclectically contacts with the plurality of metal terminals (not shown) mounted within the insulator housing 602.

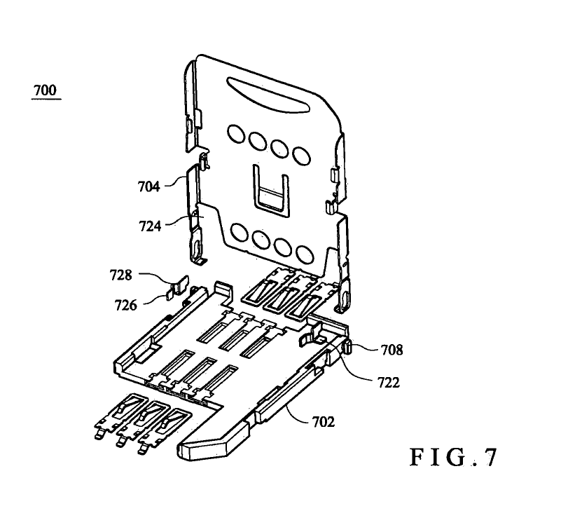

The structure of the insulator housing will be further described as below. As shown in FIG. 7, the insulator housing 702 includes at least one metal positioning portion 722 and a symmetrical trough 724 that forms on the lateral wall of the shell 704 and disposed at the same side with the pivot bearing 708. Wherein, the middle section of the metal positioning portion 722 includes a raised bent neck 726 and an end portion 728 connecting to the bent neck 726. When the insulator housing 702 and the shell 704 are closed, the end portion 728 is firmly stocked within the symmetrical trough 724 so that the SIM card is firmly fixed within the card connection apparatus 700 to generate an electrical connection. Except for the above-mentioned SIM card of the embodiment according to the invention, any other IC cards or chip cards used in data accessing, data storage or signal transmitting processing applied in a portable digital electric device or a communication device are covered within the scope of the equivalent devices of the card connection apparatus according to the invention under a reasonable expansion.

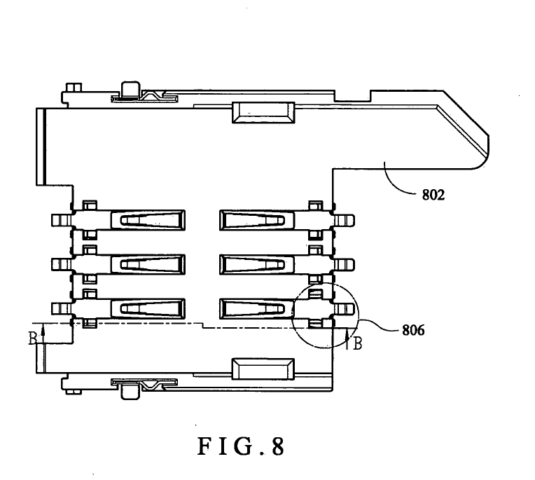

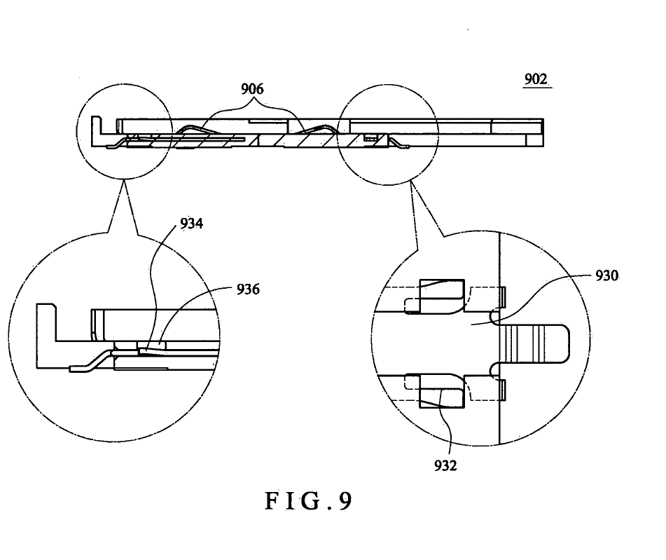

FIG. 8 is a partially enlarged diagram illustrating the shell provided by the invention. As shown in the figure, metal terminals 806 are located within the insulator housing 802 to provide an electrical connection to the chip. As shown in FIG. 9, the metal terminal 906 includes a terminal body 930 and holding pieces 932 integrally formed with the left or right sides of the terminal body 930. The holding pieces 932 integrally formed with the left or right sides of the terminal body 930 may interfere with the chip against the direction of the movement of metal terminals 906 so as to fix the metal terminals 906 within the insulator housing 902. Each of the metal terminals 906 further includes an upward portion 934, and a slug hole 936 fixed on the inside of the insulator housing 902. The above-mentioned holding pieces 932 and upward portions 934 of the metal terminals 906, when being connected with the insulator housing 902, would not cause the deformation of the insulator housing 902. Moreover, stronger retaining force would be provided for the insulator housing 902 and the shell (not shown) to ensure the electrical contacts between the metal terminals 906 and the SIM card (not shown), so that the data stored within the SIM card can be accessed stably.

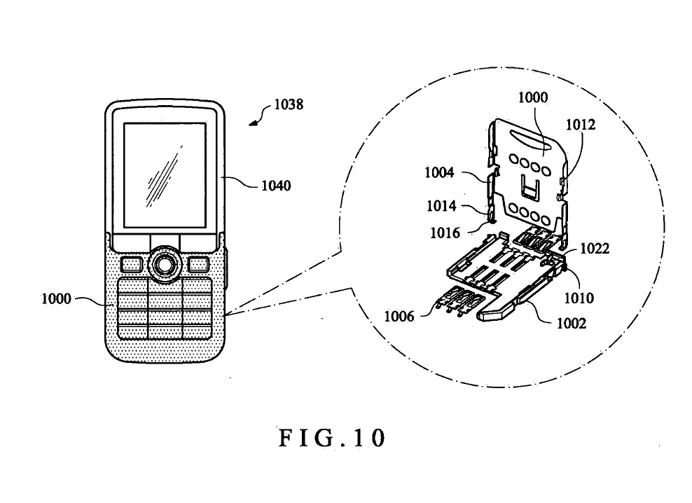

FIG. 10 schematically illustrates the installation of the card connection apparatus on a wireless communication device such as a cell phone. As shown in the figure, the wireless communication device 1038 includes a case shell 1040, a motherboard (not shown), a wireless signal transmitter/receiver (not shown) and a card connection apparatus 1000 mounted on the case shell 1040. The card connection apparatus 1000, similar to the ones described above, includes an insulator housing 1002, a shell 1004, and a plurality of metal terminals 1006 installed within the insulator housing 1002. The insulator housing 1002 is made of plastic. Paired pivot bearings (not shown) are set up on the nook of the lateral wall of the insulator housing 1002, and the end of each of the pivot bearings (not shown) is joined to a resistive cylinder 1010 having an internal diameter bigger than that of the pivot bearing (not shown). The shell 1004 is made of metal and used to seal the insulator housing 1002. At least a holding portion 1012 is formed on the edge of the shell 1004 for holding the shell 1004. The shell 1004, at the same side of the holding portion 1012, further includes lateral walls that have been formed with a plurality of long pivot slits 1014 in order to provide a passage for the resistive cylinder 1010.

The shell 1004 of the card connection apparatus 1000 is pivotally connected to the insulator housing 1002 so as to rotate freely on the axle formed by pivot bearings 1008 (not shown). The end of the long pivot slit 1014 of the shell 1004 is further established an L-shaped bending portion 1016. The L-shaped bending portion 1016 is made of metal. It hooks the resistive cylinder 1010 while the shell 1004 is closed to provide firm retaining force for the shell 1004 and the insulator housing 1002 in the vertical direction. Accordingly, the shell 1004 is firmly fixed to the insulator housing 1002 by the L-shaped bending portion 1016 and thus facilitates the operation of the user.

Similar to the above-mentioned embodiment, the card connection apparatus 1000 preferably includes a structure the same as those of the above-mentioned metal positioning portions 1022 and the metal terminals 1006. These identical structures would not be repeatedly described in details here.

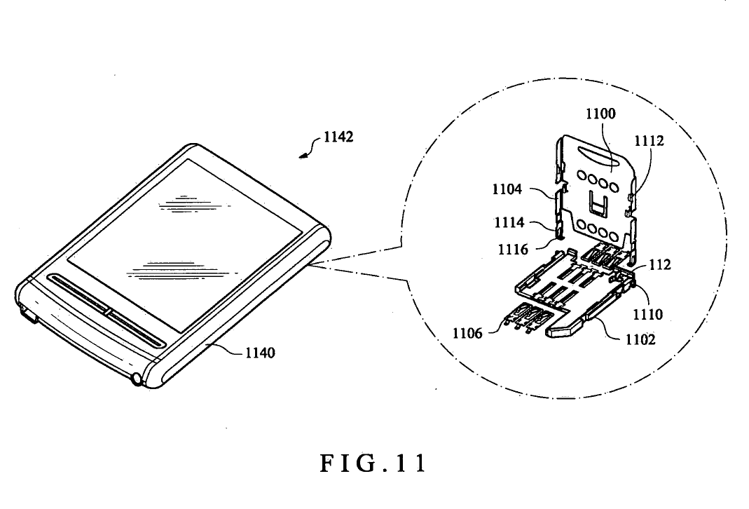

FIG. 11 discloses a card connection apparatus according to the invention applied within a digital electric device. The digital electric device might be any device having a card connection apparatus, e.g. a copy machine, a portable computer, a desktop computer, a Digital Multimedia Broadcasting (DMB) device, a game console, an electric storage displaying media (such as the electric paper), a mobile communication device such as a cell phone, a Personal Digital Assistant (PDA), a Global Positioning System (GPS), a POS, a POI, a karaoke machine, a video phone, a hand-held data processor, a digital billboard, a television wall, an Automated Teller Machine (ATM), a stock trade system, and a tour guide system, etc . . . The relationship between any of the digital electric device mentioned above and the card connection apparatus is equivalent to the one shown in FIG. 11.

Please refer to FIG. 11. FIG. 11 schematically illustrates the installation of the card connection apparatus according to the invention on a digital electric device such as a PDA. As shown in the figure, the PDA 1142 includes a case shell 1140, a motherboard (not shown) and a card connection apparatus 1100 installed on the case shell 1140. The card connection apparatus 1100, similar to the ones described above, includes an insulator housing 1102, a shell 1104, and a plurality of metal terminals 1106 installed within the insulator housing 1102. The insulator housing 1102 is made of plastic. Paired pivot bearings (not shown) are set up on the nook of the lateral wall of the insulator housing 1102, and the end of each of the pivot bearings (not shown) is joined to a resistive cylinder 1110 having an internal diameter bigger than that of the pivot bearing (not shown). The shell 1104 can be made of metal and is used for sealing the insulator housing 1102. At least one holding portion 1112 is located on the edge of the shell 1104 for holding the shell 1104, and, at the same side of the holding portion 1112, a plurality of long pivot slits 1114 are opened at the lateral wall of the shell 1104 in order to provide a passage for the resistive cylinder 1110.

The shell 1104 of the card connection apparatus 1100 is pivotally connected to the insulator housing 1102 so as to rotate freely on the axle formed by pivot bearings 1108 (not shown). The end of the long pivot slit 1114 of the shell 1104 is further established an L-shaped bending portion 1116. The L-shaped bending portion 1116 is made of metal. It hooks the resistive cylinder 1110 while the shell 1104 is closed to provide firm retaining force for the shell 1104 and the insulator housing 1102 along the vertical direction. Accordingly, the shell 1104 is firmly fixed to the insulator housing 1102 by the L-shaped bending portion 1116 and thus facilitates the operation of the user.

Similar to the above-mentioned embodiment, the card connection apparatus 1100 preferably includes a structure the same as those of the above-mentioned metal positioning portions 1122 and the metal terminals 1106. These identical structures would not be repeatedly described in details here.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A card connection apparatus for connecting with a chip, comprising:
an insulator housing having paired pivot bearings set up on a nook of a lateral wall of said insulator housing, wherein an end of said pivot bearing being joined to a resistive cylinder having an internal diameter bigger than that of one of said pivot bearings;
a shell used to seal said insulator housing, wherein at least one holding portion is provided on an edge of said shell, and a plurality of long pivot slits are opened on a lateral wall of said shell at an identical side of said holding portion in order to provide a passage for said resistive cylinder, and an L-shaped bending portion being further established at an end of said long pivot slit for hooking said resistive cylinder when said shell is closed; and
a plurality of metal terminals installed within said insulator housing for providing an electrical connection with said chip, wherein each of said metal terminals includes a terminal body and holding pieces integrally formed with the left and right sides of said terminal body, and when said chip is inserted into said shell, said holding pieces would interfere with said chip against a direction of a movement of said metal terminals so as to fix said metal terminals within said insulator housing.

2. A card connection apparatus according to claim 1, further comprises a metal positioning portion and a symmetrical trough formed on a lateral wall of said shell and disposed on an identical side of said pivot bearing, wherein a middle section of said metal positioning portion includes a raised bent neck and an end portion connecting to said bent neck and stocked within said symmetrical trough.

3. A card connection apparatus according to claim 1, wherein said chip is a subscriber identity module card.

4. A card connection apparatus according to claim 1, wherein said shell is pivotally connected to said insulator housing so as to rotate freely on an axle formed by said pivot bearings.

5. A card connection apparatus according to claim 1, wherein said shell is made of metal.

6. A card connection apparatus according to claim 1, wherein said insulator housing is made of plastic.

7. A card connection apparatus according to claim 1, wherein said long pivot slit includes an L-shaped bending portion fixing said shell on said insulator housing along a vertical direction.

8. A card connection apparatus according to claim 1, wherein said L-shaped bending portion of said long pivot slit is made of metal.

9. A card connection apparatus according to claim 1, wherein said long pivot slit includes a first receiving hole and a second receiving hole, and two circle centers are located in the said first receiving hole and said second receiving hole respectively.

10. A card connection apparatus according to claim 9, wherein when said pivot bearing of said insulator housing is moved from said first receiving hole to said second receiving hole, an end portion of said shell near said pivot bearing is raised to provide a space for said chip to slip into said insulator housing.

11. A card connection apparatus according to claim 1, wherein each of said metal terminals includes an upward portion, and said upward portion being fixed on a slug hole inside of said insulator housing.

12. A wireless communication device equipped with a card connection apparatus for connecting with a chip, comprising a case shell; a motherboard; a wireless signal transmitter/receiver; and said card connection apparatus mounted on said case shell; said card connection apparatus comprising:
an insulator housing having paired pivot bearings set up on a nook of a lateral wall of said insulator housing and an end of each of said pivot bearings being joined to a resistive cylinder having a bigger internal diameter than that of one of said pivot bearings;
a shell used to seal said insulator housing, wherein at least one holding portion is provided on an edge of said shell for holding said shell, and a plurality of long pivot slits are opened on a lateral wall of said shell at an identical side of said holding portion in order to provide a passage for said resistive cylinder, wherein an L-shaped bending portion is further established at an end of said long pivot slit for hooking said resistive cylinder when said shell is closed; and
a plurality of metal terminals installed within said insulator housing for providing an electrical connection with said chip, wherein each of said metal terminals includes a terminal body and holding pieces integrally formed with the left and right sides of said terminal body, and when said chip is inserted into said shell, said holding pieces would interfere with said chip against a direction of a movement of said metal terminals so as to fix said metal terminals within said insulator housing.

13. A digital electric device comprising a card connection apparatus for connecting with a chip, wherein said digital electric device is selected from a group comprising a mobile communication device, a copy machine, a fax machine, a multi-function business machine, a Global Positioning System (GPS), an Automated Teller Machine (ATM), a Point Of Sale (POS), and a Point Of Interest (POI), wherein said card connection apparatus comprises:
an insulator housing having paired pivot bearings set up on a nook of a lateral wall of said insulator housing, wherein an end of said pivot bearing is joined to a resistive cylinder having an internal diameter bigger than that of one of said pivot bearings;
a shell used to seal said insulator housing, wherein at least one holding portion is provided on an edge of said shell for holding said shell, and a plurality of long pivot slits are opened on a lateral wall of said shell at an identical side of said holding portion in order to provide a passage for said resistive cylinder, and an L-shaped bending portion is further established at an end of said long pivot slit for hooking said resistive cylinder when said shell is closed; and
a plurality of metal terminals installed within said insulator housing for providing an electrical connection with said chip, wherein each of said metal terminals includes a terminal body and holding pieces integrally formed with the left and right sides of said terminal body, and when said chip is inserted into said shell, said holding pieces would interfere with said chip against a direction of a movement of said metal terminals so as to fix said metal terminals within said insulator housing.
